(19) United States
(12) Patent Application Publication
(10) Pub. No.: US 2012/0280717 A1
(43) Pub. Date: Nov. 8, 2012

(54) Method For Arc Detection And Devices Thereof

(76) Inventor: Junhua Fu, Nanjing (CN)

(21) Appl. No.: 13/515,159

(22) PCT Filed: Dec. 11, 2009
(86) PCT No.: PCT/CN09/75494

§ 371 Date: Jul. 27, 2012

(51) Int. Cl. G01R 29/02

(52) U.S. Cl. 327/14

(57) ABSTRACT

A method for arc detection includes detecting a changing rate of a signal indicative of light strength, detecting the amplitude of the signal, and indicating an occurrence of an arc if the changing rate of the signal exceeds a first predetermined threshold and the amplitude of the signal exceeds a second predetermined threshold. An arc detecting device, an arc detecting system, and an arc protecting apparatus thereof are provided. The arc detecting system includes a light collector (101) for collecting light, a light converter (103) coupled to the light collector (101) for converting the collected light into an electric signal, and an arc detecting device (106) coupled to the light converter (103) for detecting the occurrence of the arc. The arc detecting device (106) comprises a slope criterion module configured to determine if the changing rate of the signal indicative of the light strength exceeds the first predetermined threshold and an absolute value criterion module configured to determine if the amplitude of the signal exceeds the second predetermined threshold.

### FIELD OF THE INVENTION

The present invention relates to arc protection, and more specifically, to a method for arc detection and devices thereof.

### BACKGROUND

Electrical arcing occurs when the voltage difference between two conductors is sufficient to cause a breakdown of the gas separating them.

Electrical arcing produces a great deal of heat which can lead to damage to equipment and initiation of fires and most importantly injury to workers. Therefore, it is desirable to be able to monitor equipment for the instigation of electrical arcing and to be able to quickly shut off the area at fault to extinguish this arc.

This is critical to arc detection technology. If the arc can be detected quickly the protection systems can isolate the equipment at fault, cutting off supplies and hence avoiding further damage to the equipment itself, neighboring devices and most importantly reduce the chance of injury to workers. However, if the supplies cannot be cut off in around 100 ms, arc-flash hazard will be produced.

Traditional arc protective relays, such as REA101 provided by ABB Ltd., VAMP211 provided by VAMP Ltd., employ an absolute value criterion to determine the occurrence of the electrical arcing. If the voltage of the detected light signal exceeds a predetermined threshold, the light is determined to be an arc. Because of the interference of the ambient light, the choice of the threshold for the arc detection cannot be precise. If the threshold is too big, the device may miss the arc flash, while if too small the ambient light may be mistakenly detected as the arc flash. Conventionally, such threshold is chosen at a high level and is not adjustable, which may render the arc detection incorrect. To overcome the deficiency, some providers of the arc protective relays employ an adjustable accuracy button to adapt for different ambient light. However, the use of such accuracy button has two main disadvantages. Firstly, it may introduce some difficulty and uncertain problem to the installation. For the buyers who may want to combine the protective relay into their device, it is not easy to choose the right accuracy level, and will introduce some risk to the client if they choose the improper level. Secondly, it is indeed impossible to choose a perfect accuracy level. The environment is uncertain and may be changing. If one settled threshold is chosen it may introduce many restriction when the device is being used, which may not be acceptable to the customer.

PCT patent application (publication No. WO 88/08217), entitled “An Arc Relay” introduces an arc relay and describes the use of fiber optics to detect arcing in relays and the associated electronics. Of particular interest is its detailing of the use of looped and un-clad optic fiber as a detector. However, this patent application also uses the absolute value of light as an arc detection criterion.

Therefore, it is to an improved arc detecting method and devices thereof that are capable of improving the arc detection accuracy that the present invention is primarily directed.

### SUMMARY

Detailed herein is a technology which, among other things, allows an arc relay to detect an arc-flash precisely and instantly and allows such arc relay to be integrated into an electronic device easily. In addition, such arc relay also makes the installation and the running environment simple.

In one aspect of the invention, a slope detecting device for detecting a slope of a signal is provided according to one embodiment of the present invention. The slope detecting device includes a delay module configured to delay the signal indicative of the light strength by a predetermined time period and output a delayed signal; a subtraction module configured to subtract a predetermined threshold from the signal indicative of the light strength and output a subtracted signal; and a comparator configured to compare the delayed signal and the subtracted signal and output a signal indicating that an arc is detected if the subtracted signal exceeds the delayed signal within the predetermined time period. The comparator outputs no signals if the subtracted signal does not exceed the delayed signal within the predetermined time period.

In another aspect of the invention, an arc detecting device is provided according to one embodiment of the present invention. The arc detecting device includes a slope criterion module configured to determine if a changing rate of a signal indicative of the light strength exceeds a first predetermined threshold; and an absolute value criterion module configured to determine if the amplitude of the signal exceeds a second predetermined threshold. Once the changing rate of the signal exceeds the first predetermined threshold and the amplitude of the signal exceeds the second predetermined threshold, the arc detecting device outputs a signal indicating the occurrence of an arc flash. In one embodiment, the slope criterion module may include a first order delay module, a subtraction module and a comparator.

In another aspect of the invention, an arc detecting system is provided according to one embodiment of the present invention. The arc detecting system includes a light collector for collecting light; a light converter coupled to the light collector for converting the collected light into an electrical signal; an arc detecting device coupled to the light converter for detecting the occurrence of an arc. The arc detecting device includes a slope criterion module configured to determine if a changing rate of a signal indicative of the light strength exceeds a first predetermined threshold; and an absolute value criterion module configured to determine if the amplitude of the signal exceeds a second predetermined threshold. Once the changing rate of the signal exceeds the first predetermined threshold and the amplitude of the signal exceeds the second predetermined threshold, the arc detecting device outputs a signal indicating the occurrence of an arc flash. In one embodiment, the slope criterion module may include a first order delay module, a subtraction module and a comparator.

In another aspect of the invention, an arc protection apparatus is provided according to one embodiment of the present invention. The arc protection apparatus includes a current detecting module for detecting a fault current; and an arc detecting system coupled to the current detecting module. The arc detecting system includes a light collector for collecting light; a light converter coupled to the light collector for converting the collected light into an electrical signal; an arc detecting device coupled to the light converter for detecting the occurrence of an arc flash. The arc detecting device includes a slope criterion module configured to determine if a changing rate of a signal indicative of the light strength exceeds a first predetermined threshold; and an absolute value criterion module configured to determine if the amplitude of the signal exceeds a second predetermined threshold. Once the changing rate of the signal exceeds the first predetermined threshold and the amplitude of the signal exceeds the second predetermined threshold, the arc detecting device outputs a signal indicating the occurrence of an arc flash. In one embodiment, the slope criterion module may include a first order delay module, a subtraction module and a comparator.

In yet another aspect of the invention, a method for detecting an arc is provided according to one embodiment of the present invention. The method includes detecting a changing rate of a signal indicative of the light strength; detecting the amplitude of the signal; and indicating an occurrence of an arc if the changing rate of the signal exceeds a first predetermined threshold and the amplitude of the signal exceeds a second predetermined threshold.

It is to be noted that this Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

In the drawings, each identical or nearly identical component that is illustrated in various figures is represented by a like numeral. For purposes of clarity, not every component may be labeled in every drawing. In the drawings:

FIG. 1 is a schematic diagram of an arc detecting system according to one embodiment of the present invention;

FIG. 2 is a schematic diagram of an implementation of an arc detecting device according to one embodiment of the present invention;

FIG. 3 is a time sequence chart of the arc detecting device according to one embodiment of the present invention;

FIG. 4 is a time sequence chart of the arc detecting device according to one embodiment of the present invention; and

FIG. 5 is flow chart of a method for detecting an arc according to one embodiment of the present invention.

### DETAILED DESCRIPTION

Embodiments are herein described more fully below with reference to the accompanying drawings, which form a part hereof, and which show specific examples for practicing the embodiments. However, embodiments may be implemented in many different forms and should not be construed as limited to the embodiments set forth herein; rather, these embodiments are provided so that this disclosure will be thorough and complete, and will fully convey the scope of the subject matter to those skilled in the art. Embodiments disclosed may be practiced as methods, systems or devices. Accordingly, embodiments disclosed may take the form of an entirely hardware implementation, an entirely software implementation or an implementation combining software and hardware aspects. The following detailed description is, therefore, not to be taken in a limiting sense.

The arc flash has two main characters. One is that the light strength of the arc flash is very strong, more or less than the sunlight. The other is that the light of the arc flash changes fast. The arc flash will burn out in no more than one microsecond, which is very different from other types of the ambient light except the lightning. Based on these two characters, the present invention adopts a signal slope criterion for arc detection. With such criterion, the interference of the ambient light may thus be mitigated. Furthermore, to avoid the influence of weak but fast changing light signal such as lightning for example, a traditional absolute value criterion may be adopted as an assistant criterion, in which a small settled threshold may be chosen.

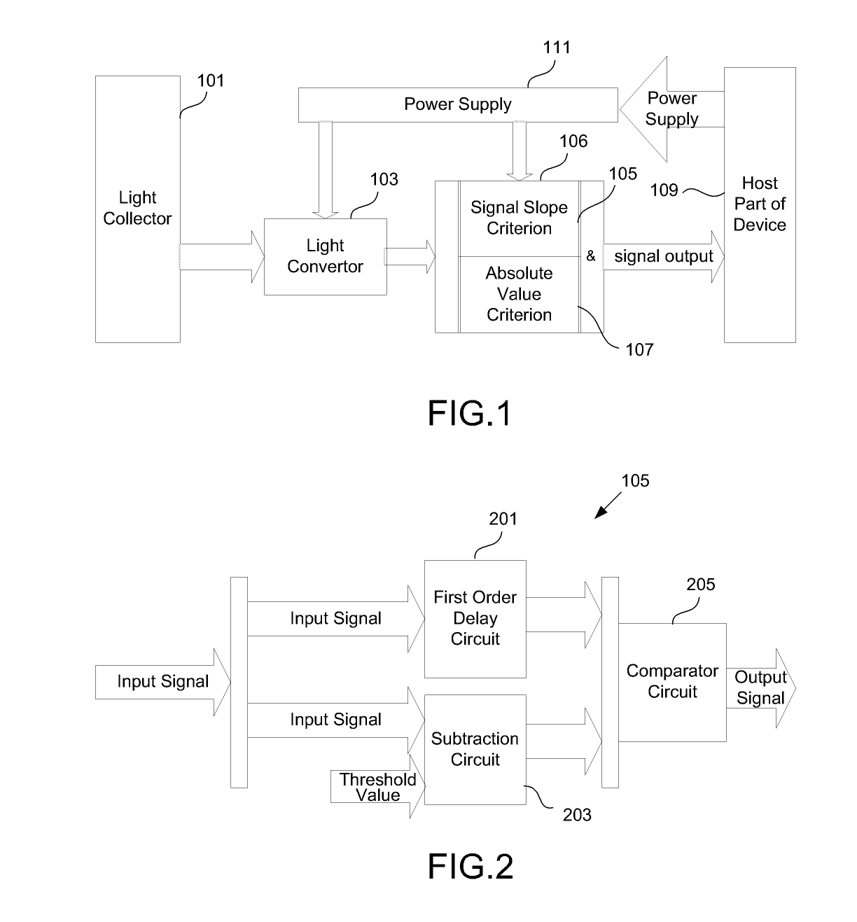

Referring to FIG. 1, a schematic diagram of an arc detecting system is illustrated. The arc detecting system herein includes a light collector 101, a light converter 103, an arc detecting device 106, and a power supply module 111. The light collector 101 is configured to receive and collect lights. The light converter 103 coupled to the light collector 101 is configured to convert the input light into an electrical signal which indicates the light strength. The arc detecting device 106 is configured to detect the occurrence of an arc based on the converted electrical signal and output a signal indicating the occurrence of an arc to the host part of the device. In particular, the arc detecting device 106 may include a signal slope criterion module 105 (also known as a slope detecting device) and an absolute value criterion module 107. In one embodiment, the arc detecting system may share the power supply from the host device.

According to the present invention, the arc detecting device 106 employs both a traditional absolute value criterion which detects the arc flash by the absolute value and a signal slope criterion which detects the arc flash by the changing rate, or the slope of the signal, which is a novelty point of the present invention. The signal slope criterion module 105 sets a first predetermined threshold of the slope of the input signal and determines if the slope of the input signal exceeds the first predetermined threshold. The absolute value criterion module 107 sets a second predetermined threshold of the amplitude of the input signal and determines if the amplitude of the input signal exceeds the second predetermined threshold. These two modules cooperate with each other to determine if an arc occurs. It is to be noted that the absolute value criterion is an assistant criterion in case the input light is small and the slope of the input light is sharp. If the slope of the input signal exceeds the first predetermined threshold and the amplitude of the input signal exceeds the second predetermined threshold, the arc detecting device 106 outputs a signal indicating that an arc flash occurs. If the slope of the input signal exceeds the first predetermined threshold but the amplitude of the input signal is below the second predetermined threshold, the arc detecting device 106 generates no output, which means that the input light is not an arc flash. If the slope of the input signal is below the first predetermined threshold but the amplitude of the input signal exceeds the second predetermined threshold, the arc detecting device 106 generates no output, which means that although the strength of the input light is high enough, the input light changes slowly and the input light therefore shall not be regarded as an arc flash. If the slope of the input signal is below the first predetermined threshold and the amplitude of the input signal is below the second predetermined threshold, the arc detecting device 106 generates no output.

In one embodiment, the arc detecting system may be coupled to a current detecting module (not shown) for detecting the current to see if an arc flash occurs. The arc detecting system and the current detecting module together may constitute an arc protective relay module (also referred to as an arc protection apparatus) which can be integrated into the motherboard of an electronic device in the form of an extended card.

FIG. 2 illustrates a schematic diagram of an exemplary implementation of the signal slope criterion module 105 shown in FIG. 1. In one embodiment, the arc detecting device 106 includes a delay module 201, a subtraction module 203 and a comparator 205.

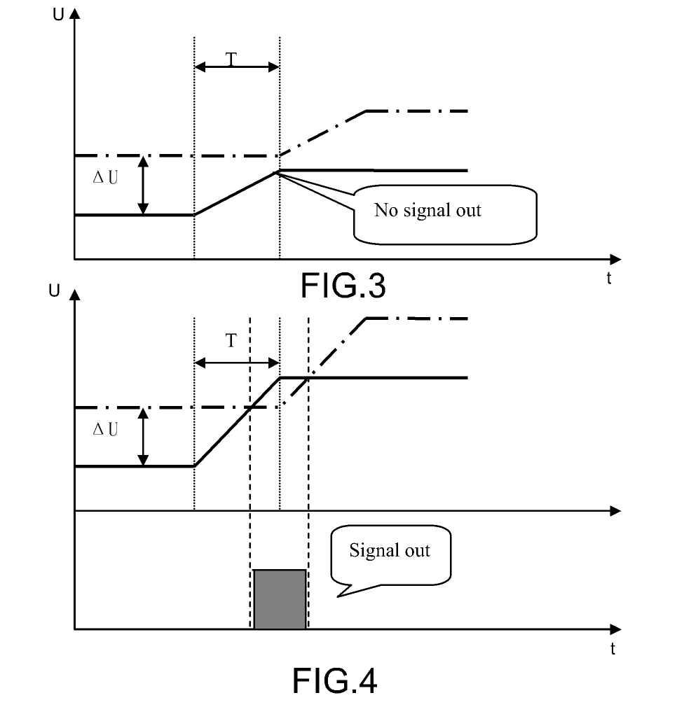

The delay module 201 may set a time delay T. That is, the delay module 201 delays the input signal by a predetermined time period T. In one embodiment, the delay module 201 may be a first order delay circuit. The subtraction module 203 sets a predetermined threshold value ΔU. The subtraction module 203 subtracts ΔU from the input signal and outputs a subtracted signal. The comparator 205 then compares the delayed signal and the subtracted signal within the predetermined time period T and output a signal indicating that an arc is detected if the subtracted signal exceeds the delayed signal within the predetermined time period, see FIG. 3. The comparator 205 generates no output if the subtracted signal is below the delayed signal, see FIG. 4. As a result, the signal slope criterion module 105 actually compares the slope of the input signal with a predetermined threshold, i.e., ΔU/T, within a predetermined time period T. As can be seen, the arc detecting device is mainly focused on the changing rate of the input signal rather than solely on the traditional absolute value of the signal.

Referring to FIG. 3, a time sequence chart of the arc detecting device according to one embodiment of the present invention is illustrated. The dash line refers to the delayed signal which serves as the reference signal of the comparator. The solid line refers to the subtracted signal which serves as another input of the comparator. In this chart, the subtracted signal is lower than the delayed signal, which means that the slope of the input signal is less than ΔU/T. The signal slope criterion module generates no signal.

Referring to FIG. 4, a time sequence chart of the arc detecting device according to one embodiment of the present invention is illustrated. In this chart, when the subtracted signal exceeds the delayed signal within the predetermined time period, which means that the slope of the input signal is higher than ΔU/T, the signal slope criterion module may thus generate a signal indicating the occurrence of an arc flash.

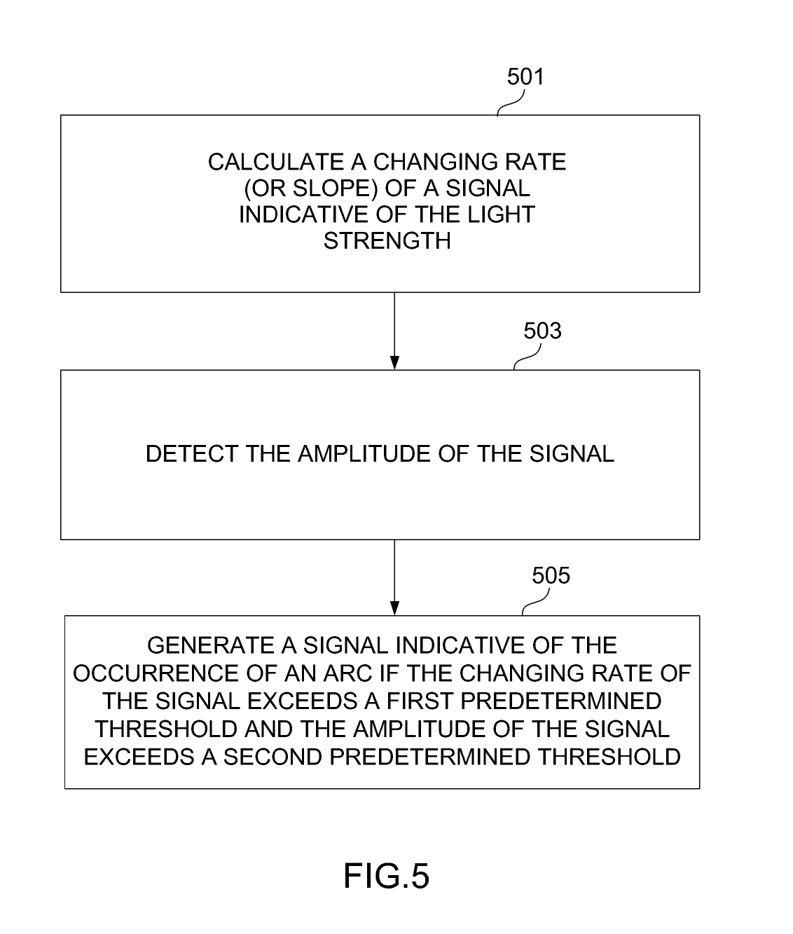

FIG. 5 illustrates a flow chart of a method for detecting the occurrence of an arc flash. At block 501, a changing rate (or slope) of a signal indicative of the light strength is calculated. At block 503, the amplitude of the signal is detected. At block 505, a signal indicative of the occurrence of an arc is generated if the changing rate of the signal exceeds a first predetermined threshold (i.e., ΔU/T) and the amplitude of the signal exceeds a second predetermined threshold. Specifically, the detecting of the changing rate of a signal indicative of the light strength includes delaying the signal by a predetermined time period ((i.e., T); subtracting a third predetermined threshold value (i.e., ΔU) from the signal; and comparing the delayed signal and the subtracted signal.

Advantageously, the present invention allows employing a much smaller and adjustable threshold for determining the occurrence of the arc flash, compared with the traditional absolute value criterion where a much larger threshold is chosen. Consequently, the arc detection accuracy is improved. Furthermore, due to the simple structure, the present invention allows the arc protective relay module to be integrated into an electronic device easily. In one embodiment, such arc protection relay module may be in the form of an extended card and thus be inserted into the motherboard of the host device.

Although the invention has been described in language specific to structural features and/or methodological acts, it is to be understood that the invention defined in the appended claims is not necessarily limited to the specific features or acts described. Rather, the specific features and acts are disclosed as exemplary forms of implementing the claimed invention.

What is claimed is:

1. A slope detecting device for detecting a slope of a signal, comprising:
a delay module configured to delay the signal indicative of the light strength by a predetermined time period and output a delayed signal;
a subtraction module configured to subtract a predetermined threshold from the signal indicative of the light strength and output a subtracted signal; and
a comparator configured to compare the delayed signal and the subtracted signal and output a signal indicating that an arc is detected if the subtracted signal exceeds the delayed signal within the predetermined time period.

2. The slope detecting device of claim 1, wherein the comparator generates no signals if the subtracted signal does not exceed the delayed signal within the predetermined time period.

3. An arc detecting device, comprising:
a slope criterion module configured to determine if a changing rate of a signal indicative of the light strength exceeds a first predetermined threshold; and
an absolute value criterion module configured to determine if an amplitude of the signal exceeds a second predetermined threshold.

4. The device of claim 3, wherein the slope criterion module comprises:
a delay module configured to delay the signal indicative of the light strength by a predetermined time period and output a delayed signal;
a subtraction module configured to subtract a third predetermined threshold from the signal indicative of the light strength and output a subtracted signal; and
a comparator configured to compare the delayed signal and the subtracted signal and output a signal indicating that an arc is detected if the subtracted signal exceeds the delayed signal within the predetermined time period.

5. The device of claim 4, wherein the first predetermined threshold is a quotient of dividing the third predetermined threshold by the predetermined time period.

6. The device of claim 4, wherein the comparator generates no signals if the subtracted signal does not exceed the delayed signal within the predetermined time period.

7. The device of claim 4, wherein the delay module is a first order delay circuit.

8. An arc detecting system, comprising:
a light collector for collecting light;
a light converter coupled to the light collector for converting the collected light into an electrical signal;
an arc detecting device coupled to the light converter for detecting the occurrence of an arc, comprising:
a slope criterion module configured to determine if a changing rate of a signal indicative of the light strength exceeds a first predetermined threshold; and
an absolute value criterion module configured to determine if an amplitude of the signal exceeds a second predetermined threshold.

9. The arc detecting system of claim 8, wherein the slope criterion module comprises:
a delay module configured to delay the signal indicative of the light strength by a predetermined time period and output a delayed signal;
a subtraction module configured to subtract a third predetermined threshold from the signal indicative of the light strength and output a subtracted signal; and
a comparator configured to compare the delayed signal and the subtracted signal and output a signal indicating that an arc is detected if the subtracted signal exceeds the delayed signal within the predetermined time period.

10. The arc detecting system of claim 9, wherein the first predetermined threshold is a quotient of dividing the third predetermined threshold by the predetermined time period.

11. The arc detecting system of claim 9, wherein the comparator generates no signals if the subtracted signal does not exceed the delayed signal within the predetermined time period.

12. The arc detecting system of claim 9, wherein the delay module is a first order delay circuit.

13. An arc protection apparatus, comprising:
a current detecting module for detecting a fault current; and
an arc detecting system coupled to the current detecting module, wherein the arc detecting system comprising:
a light collector for collecting light;
a light converter coupled to the light collector for converting the collected light into an electrical signal;
an arc detecting device coupled to the light converter for detecting the occurrence of an arc, comprising:
a slope criterion module configured to determine if a changing rate of a signal indicative of the light strength exceeds a first predetermined threshold; and
an absolute value criterion module configured to determine if an amplitude of the signal exceeds a second predetermined threshold.

14. The arc protection apparatus of claim 13, wherein the slope criterion module comprises:
a delay module configured to delay the signal indicative of the light strength by a predetermined time period and output a delayed signal;
a subtraction module configured to subtract a third predetermined threshold from the signal indicative of the light strength and output a subtracted signal; and
a comparator configured to compare the delayed signal and the subtracted signal and output a signal indicating that an arc is detected if the subtracted signal exceeds the delayed signal within the predetermined time period.

15. The arc protection apparatus of claim 14, wherein the first predetermined threshold is a quotient of dividing the third predetermined threshold by the predetermined time period.

16. The arc protection apparatus of claim 14, wherein the comparator generates no signals if the subtracted signal does not exceed the delayed signal within the predetermined time period.

17. The arc protection apparatus of claim 14, wherein the delay module is a first order delay circuit.

18. A method for detecting an arc, comprising:
detecting a changing rate of a signal indicative of the light strength;
detecting an amplitude of the signal; and
indicating an occurrence of an arc if the changing rate of the signal exceeds a first predetermined threshold and the amplitude of the signal exceeds a second predetermined threshold.

19. The method claim 18, wherein detecting a changing rate of a signal indicative of the light strength comprises:
delaying the signal by a predetermined time period;
subtracting a third predetermined threshold value from the signal; and
comparing the delayed signal and the subtracted signal.

20. The method of claim 19, wherein the first predetermined threshold is a quotient of dividing the third predetermined threshold by the predetermined time period.
